(19) United States
(12) Patent Application Publication
(10) Pub. No.: US 2025/0391740 A1
(43) Pub. Date: Dec. 25, 2025

(54) PRESS-FIT TERMINAL AND SEMICONDUCTOR DEVICE

(71) Applicant: FUJI ELECTRIC CO., LTD., Kawasaki-shi (JP)

(72) Inventor: Masayoshi SHIMODA, Kawasaki-shi (JP)

(73) Assignee: FUJI ELECTRIC CO., LTD., Kawasaki-shi (JP)

(21) Appl. No.: 19/224,250

(22) Filed: May 30, 2025

(30) Foreign Application Priority Data
Jun. 21, 2024 (JP) 2024-100094

(51) Int. Cl. H01L 23/49; H01L 23/13; H01R 12/58

(52) U.S. Cl. CPC H01L 23/49; H01L 23/13; H01R 12/585

(57) ABSTRACT

A press-fit terminal, including: a base portion; and a pair of branched portions that are branched from the base portion, the pair of branched portions being separated from each other and being curved, each branch portion having a distal end, a maximum length portion, and a root portion, the two root portions being connected to the base portion, the two distal ends approaching each other, and the two maximum length portions having a maximum separation distance in a deformation direction. The pair of branched portions are elastically deformable to be press-fitted, in a press-fitting direction perpendicular to the deformation direction, into an insertion hole. Each of the pair of branched portions includes a hardened region, which is located closer to the root portion of said each branched portion than to the maximum length portion of said each branched portion in the deformation direction.

### CROSS-REFERENCE TO RELATED APPLICATIONS

This application is based upon and claims the benefit of priority to Japanese Patent Application No. 2024-100094, filed on Jun. 21, 2024, the entire contents of which are incorporated herein by reference.

### BACKGROUND OF THE INVENTION

### 1. TECHNICAL FIELD

The present invention relates to a press-fit terminal and a semiconductor device including the press-fit terminal.

### 2. DESCRIPTION OF THE RELATED ART

In the related art, a semiconductor device includes a circuit substrate on which a semiconductor element such as an Insulated Gate Bipolar Transistor (IGBT) has been mounted, and is used for an inverter device or the like. In such a semiconductor device, a press-fit terminal that is press-fitted into an insertion hole such as a through hole of a substrate and is elastically deformed may be used (see, for example, JP 2017-126786 A).

### SUMMARY OF THE INVENTION

When a peripheral edge of the cross section perpendicular to a press-fitting direction is angular, a press-fit terminal comes into point contact with an inner peripheral wall at a time of press-fitting into an insertion hole of a substrate, and, for example, a plating layer of the insertion hole is scraped, that is, the insertion hole is damaged. On the other hand, there is a case where, when a curved shape is provided at the peripheral edge of the above cross section of the press-fit terminal, even if the damage on the insertion hole can be prevented, an insertion load may fall below a lower limit standards value.

An object of the present invention is to provide a press-fit terminal and a semiconductor device that can satisfy performance required for the press-fit terminal.

According to one aspect, a press-fit terminal includes: a base portion; and a pair of branched portions that are branched into two from a root portion on a side of the base portion while being separated from each other, have distal ends curved to approach each other, are press-fitted into an insertion hole in a press-fitting direction, and elastically deform, and the pair of branched portions include hardened regions that are located closer to a side of the root portion than a maximum length portion in a deformation direction before being press-fitted into the insertion hole. According to another aspect, a press-fit terminal includes: a base portion; and a pair of branched portions that are branched into two from a root portion on a side of the base portion while being separated from each other, have distal ends curved to approach each other, and elastically deform, and the pair of branched portions include hardened regions that are located closer to a side of the root portion than a maximum length portion at which a separation distance between the pair of branched portions is maximum.

According to still another aspect, a semiconductor device includes: the press-fit terminal; and a laminated substrate on which a semiconductor element electrically connected to the press-fit terminal is mounted.

According to the above aspect, the press-fit terminal and the semiconductor device can satisfy performance required for the press-fit terminal.

### BRIEF DESCRIPTION OF THE DRAWINGS

FIG. 1 is a cross-sectional view illustrating a semiconductor device according to one embodiment;

FIG. 2 is a front view illustrating a press-fit terminal according to the one embodiment;

FIG. 3A, FIG. 3B, FIG. 3C, and FIG. 3D are an explanatory view illustrating an example of a method for forming a hardened region according to the one embodiment;

FIG. 4A is a front view (part 1) for explaining insertion of a substrate (press-fitting of the press-fit terminal) according to the one embodiment;

FIG. 4B is a front view (part 2) for explaining insertion of a substrate (press-fitting of the press-fit terminal) according to the one embodiment;

FIG. 5 is a plan view illustrating an arc-shaped portion of an elastically deformed portion according to the one embodiment;

FIG. 6 is a plan view illustrating a round surface-shaped portion of the elastically deformed portion according to a modification;

FIG. 7 is an explanatory view illustrating a relationship between an insertion load of a press-fit terminal and a through hole diameter;

FIG. 8A is a view illustrating a simulation result of a stress distribution on an inner wall of a through hole at a time of press-fitting of the press-fit terminal according to the one embodiment;

FIG. 8B is a view illustrating a simulation result of a stress distribution on an inner wall of the through hole at the time of press-fitting of the press-fit terminal according to a comparative example;

FIG. 9 is a plan view illustrating corner part regions of the elastically deformed portion according to the comparative example; and

FIG. 10 is an explanatory view illustrating a relationship between an insertion load of a press-fit terminal and a through hole diameter according to the comparative example.

### DETAILED DESCRIPTION

Hereinafter, a press-fit terminal and a semiconductor device according to one embodiment of the present invention will be described with reference to the drawings. Note that the present invention is not limited to the embodiment described below, and can be appropriately modified and implemented within the scope not changing the gist thereof.

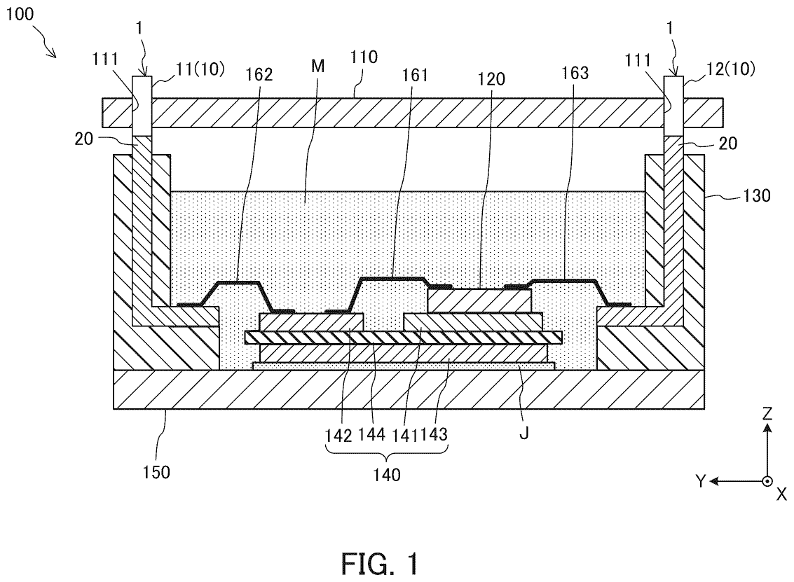

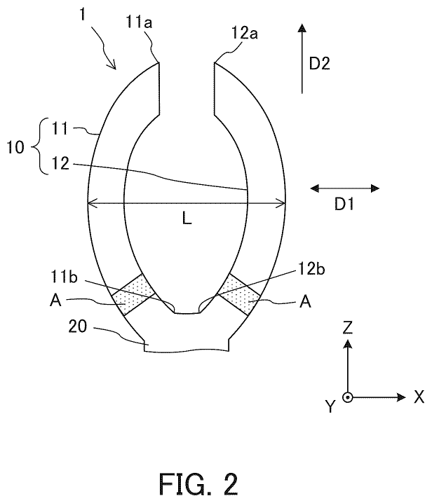

FIG. 1 is a cross-sectional view illustrating a semiconductor device 100, and FIG. 2 is a front view illustrating a press-fit terminal 1.

Note that, as for an X direction, a Y direction, and a Z direction illustrated in FIGS. 1 and 2, and FIGS. 4A to 6 and FIGS. 8A to 9 to be described later, a press-fitting direction D2 of the press-fit terminal 1 is defined as a Z direction positive side, and a deformation direction D1 of an elastically deformed portion 10 of the press-fit terminal 1 in the X direction and the Y direction perpendicular to the Z direction and perpendicular to each other is defined as the X direction. Furthermore, in some cases, the X direction may be referred to as a left-and-right direction, the Y direction may be referred to as a forward-and-rearward direction, and the Z direction may be referred to as an upward-and-downward direction. These directions are terms used for convenience of description, and the correspondence relationship between the X, Y, and Z directions changes depending on the postures of the press-fit terminal 1 and the semiconductor device 100.

As an example, the semiconductor device 100 illustrated in FIG. 1 is applied to a power conversion device such as an inverter device of an industrial or in-vehicle motor together with an unillustrated cooler disposed below a metal base 150. In the following description, detailed description of the same or similar configuration, function, operation, assembly method, and the like as or to those of the known press-fit terminal 1 and semiconductor device 100 will be omitted. Note that the press-fit terminal 1 can be also used for applications other than the semiconductor device 100 such as wiring connection and part connection in an electric device, an electronic device, a communication device, and the like.

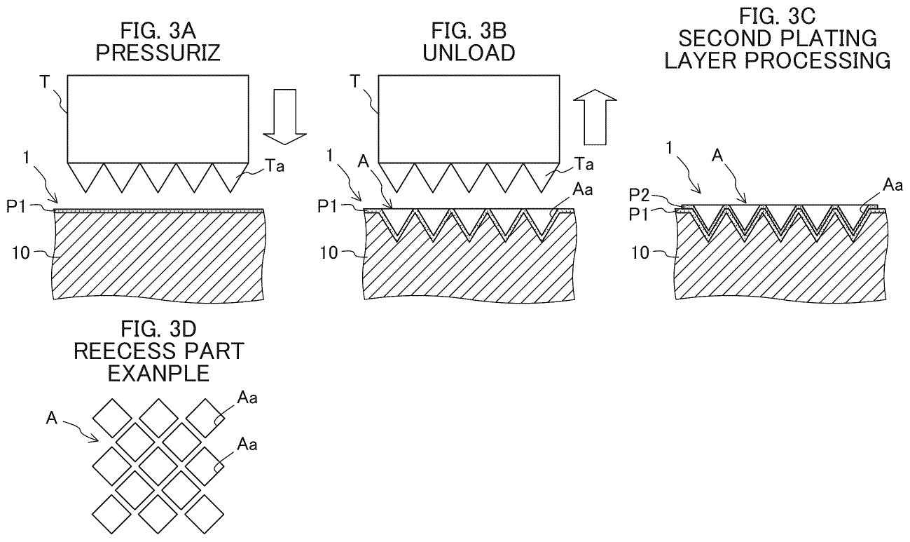

As illustrated in FIG. 2, the press-fit terminal 1 includes the elastically deformed portion 10 and a base portion 20. For example, the press-fit terminal 1 is made of a metal material such as copper, a copper alloy, brass, or stainless steel on which a first plating layer P1 (see FIG. 3A) is applied. The first plating layer P1 is, for example, Sn plating. Note that distal ends 11a and 12a of a first branched piece 11 and a second branched piece 12 are preferably formed by removing the first plating layer P1 by punching or the like to suppress production of whiskers of the first plating layer P1.

The elastically deformed portion 10 includes the first branched piece 11 and the second branched piece 12 that are an example of a pair of branched portions. The first branched piece 11 and the second branched piece 12 are branched into two from root portions 11b and 12b on the base portion 20 side toward the X direction while being separated, have the distal ends 11a and 12a in the press-fitting direction D2 with respect to a through hole 111 that are curved so as to approach each other, are press-fitted into the through hole 111, and elastically deformed. The elastically deformed portion 10 can be also referred to as a press-fitting portion or the like, and the first branched piece 11 and the second branched piece 12 can be also referred to as a U-shaped portion, a crab-claw-shaped portion, a crab-scissor-shaped portion, or the like.

Note that the elastically deformed portion 10 (the first branched piece 11 and the second branched piece 12) may have another shape such as a shape in which the distal end 11a of the first branched piece 11 and the distal end 12a of the second branched piece 12 are integrated to form an opening at the center. Furthermore, the elastically deformed portion 10 is not limited to a portion provided at an end portion on a Z direction positive side of the press-fit terminal 1, and, may be provided with, for example, a distal end portion or the like extending in the Z direction closer to the Z direction positive side than a portion at which the distal end 11a of the first branched piece 11 and the distal end 12a of the second branched piece 12 are integrated as described above. The distal end portion in this case is a non-elastically deformed portion that is not elastically deformed.

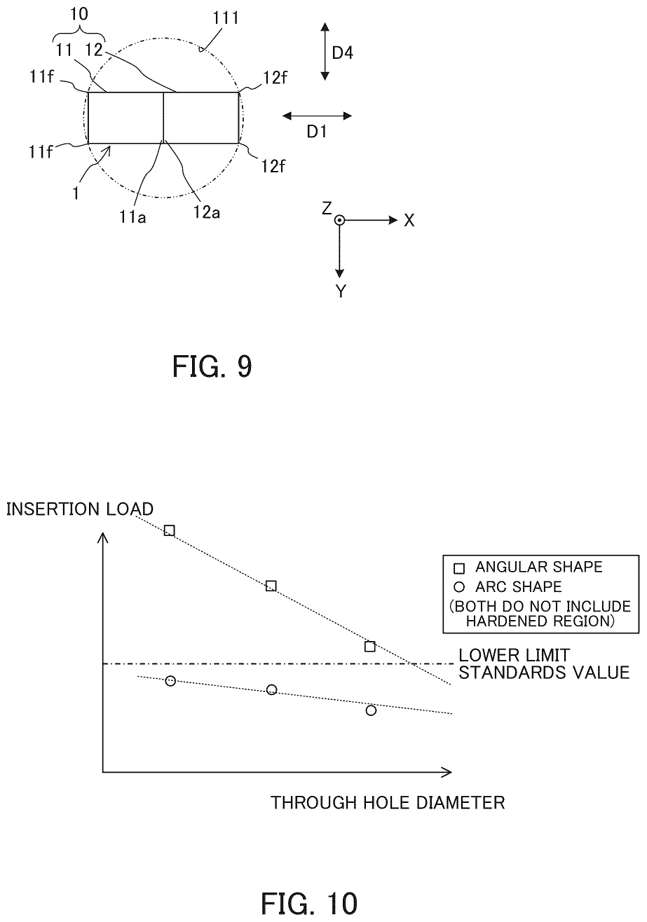

Here, a case will be considered where four corner part regions 11f and 12f that are located at the peripheral edge of the cross section perpendicular to the press-fitting direction D2 of the first branched piece 11 and the second branched piece 12 and are in contact with the through hole 111 are angular as in a comparative example illustrated in FIG. 9. In this case, as indicated by squares in FIG. 10, a press-fitting load at a time of insertion (press-fitting) of the press-fit terminal 1 into the through hole 111 decreases as the diameter of the through hole 111 increases, yet exceeds a lower limit standards value except when the diameter of the through hole 111 is too large, and satisfies the standards. This lower limit standards value is set to prevent the press-fit terminal 1 from being detached from a substrate 110 (through hole 111) due to vibration or impact to, for example, secure product reliability. However, since the four corner part regions 11f and 12f are angular, the corner part regions 11f and 12f come almost into point contact with the inner peripheral wall of the through hole 111 when the press-fit terminal 1 is press-fitted into the through hole 111. Therefore, for example, an unillustrated plating layer of the through hole 111 is scraped or the first plating layer P1 of the press-fit terminal 1 is scraped, that is, the through hole 111 and the press-fit terminal 1 are damaged. As a result, a remaining plating thickness of the unillustrated plating layer of the through hole 111 or a remaining plating thickness of the first plating layer P1 of the press-fit terminal 1 becomes small, that is, the standards of the remaining plating thickness are not satisfied.

The corner part regions 11f and 12f are four regions of an end part (corner part region 12f) on a positive side in the X direction (deformation direction D1) and on a positive side in the Y direction (a width direction D4 perpendicular to the press-fitting direction D2 and the deformation direction D1), an end part (corner part region 12f) on the positive side in the X direction and on a negative side in the Y direction, an end part (corner part region 11f) on a negative side in the X direction and on the positive side in the Y direction, and an end part (corner part region 11f) on the negative side in the X direction and on the negative side in the Y direction. Since the elastically deformed portion 10 includes the first branched piece 11 and the second branched piece 12, the two corner part regions 11f and 12f are formed at the first branched piece 11 and the two corner part regions 11f and 12f are formed at the second branched piece 12. Note that the four corner part regions 11f and 12f can be also referred to as regions that connect a side in the X direction (deformation direction D1) and a side in the Y direction (the direction perpendicular to the X direction) of the press-fit terminal 1 in a cross-sectional view perpendicular to the press-fitting direction D2. In other words, the four corner part regions 11f and 12f are regions at four corners of a rectangular region (or a substantially rectangular region) formed by the first branched piece 11, the second branched piece 12, and a region sandwiched therebetween in a cross-sectional view perpendicular to the press-fitting direction D2.

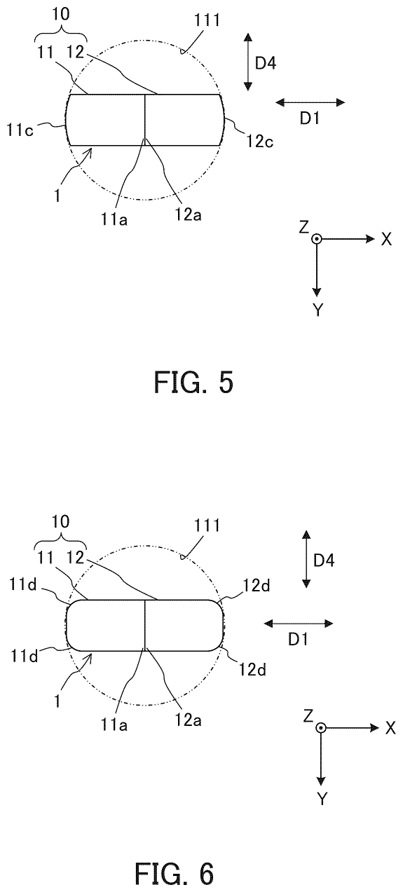

To prevent the unillustrated plating layer of the through hole 111 and the first plating layer P1 of the press-fit terminal 1 from being scraped, the first branched piece 11 and the second branched piece 12 preferably include arc-shaped portions 11c and 12c whose curvature centers are on the center side of the through hole 111 at both ends in the deformation direction D1 of the cross section (see the plan view of FIG. 5) perpendicular to the press-fitting direction D2 when press-fitted. These arc-shaped portions 11c and 12c preferably have the curvature radii whose values are equal to or close to the radius of the through hole 111 so as to fit into the through hole 111. The arc-shaped portions 11c and 12c are provided entirely over, for example, the elastically deformed portion 10 in the press-fitting direction D2, yet may be provided at at least part of the elastically deformed portion 10 that can come into contact with the through hole 111 (a portion having a larger diameter than that of the through hole 111 before press-fitting). Note that the elastically deformed portion 10 including the arc-shaped portions 11c and 12c can be formed by any molding method, a pressing method, or the like.

As described above, in a case where the first branched piece 11 and the second branched piece 12 include the arc-shaped portions 11c and 12c, it is possible to prevent the unillustrated plating layer of the through hole 111 and the first plating layer P1 of the press-fit terminal 1 from being scraped. However, as indicated by white circles in FIG. 10, an insertion load at a time of insertion (press-fitting) of the press-fit terminal 1 into the through hole 111 falls below the lower limit standards value. Note that the insertion load tends to decrease as the diameter of the through hole 111 increases, yet falls below the lower limit standards value regardless of the diameter of the through hole 111.

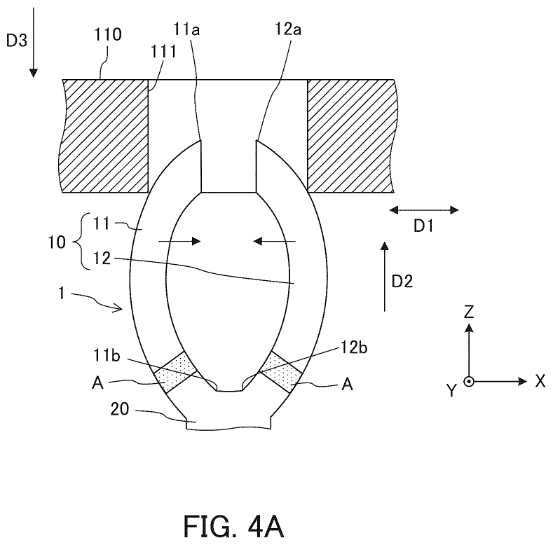

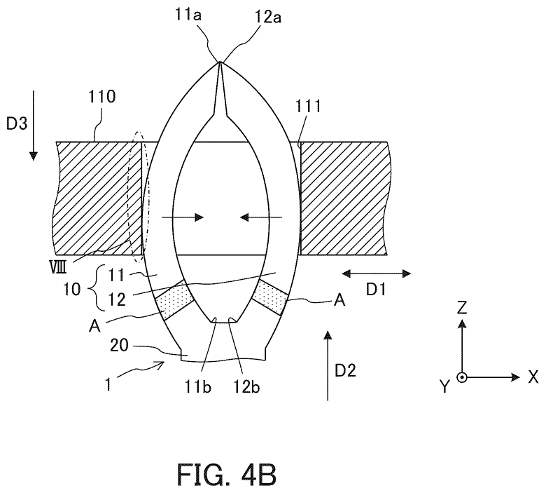

Hence, the first branched piece 11 and the second branched piece 12 preferably include hardened regions A illustrated in FIG. 2 such that the insertion load exceeds the lower limit standards value. These hardened regions A are located closer to the root portions 11b and 12b side than a maximum length (L) portion in the deformation direction D1 before press-fitting into the through hole 111. This maximum length (L) portion can be also referred to as a portion at which a separation distance between the first branched piece 11 and the second branched piece 12 is maximum. Furthermore, the hardened regions A may be located closer to the root portions 11b and 12b side than the position of the through hole 111 after press-fitting (see FIG. 4B) in the press-fitting direction D2. Here, it can be also said that, even when the hardened regions A are provided closer to both of the root portions 11b and 12b side and the distal ends 11a and 12a side than the maximum length (L) portion, the hardened regions A are located closer to the root portions 11b and 12b side than the maximum length (L) portion.

Furthermore, the hardened regions A are preferably provided on both end surfaces (a front surface and a back surface on the back side thereof illustrated in FIG. 2) of the first branched piece 11 and the second branched piece 12 in the width direction D4 (Y direction) that is illustrated in FIG. 5 and is perpendicular to the press-fitting direction D2 (Z direction) and the deformation direction D1 (X direction). In this regard, the hardened regions A may be provided on only one of the front surfaces and the back surfaces of the first branched piece 11 and the second branched piece 12. Furthermore, the lengths in the Z direction of the hardened regions A are preferably 20% or less of the length in the Z direction of the elastically deformed portion 10.

As illustrated in FIGS. 3A and 3B, the hardened regions A are pressurized by a tool T provided with a plurality of protrusion portions Ta to form a plurality of recess portions Aa. As a result, the hardened regions A have a higher yield strength than that of the other regions of the first branched piece 11 and the second branched piece 12. That is, the hardened regions A locally have a higher strength than those of the other regions of the first branched piece 11 and the second branched piece 12, and are less likely to warp at the time of press-fitting into the through hole 111. As described above, the hardened regions A are preferably formed by plastic working. Note that, although the hardened regions A can be also formed by other methods such as sandblasting, distortion hardly occurs inside the first branched piece 11 and the second branched piece 12 in a case where the hardened regions A are formed by pressing using the tool T. Furthermore, the hardened regions A are preferably formed by masking the surroundings of the hardened regions A such that machining chips having scattered around the hardened regions A do not adhere to the first branched piece 11 and the second branched piece 12.

The tool T is made of a material that is, for example, cemented carbide containing tungsten and has higher hardness than that of the press-fit terminal 1. For example, the protrusion portions Ta of the tool T have diamond shapes in plan view so as to form the recess portions Aa of diamond shapes located side by side in a zigzag manner in an example in plan view (when viewed in a pressurizing direction) illustrated in FIG. 3D. Note that the protrusion portions Ta of the tool T may have, for example, a polygonal pyramid shape such as a quadrangular pyramid shape, a conical shape, a polygonal prism shape whose distal end has a tapered shape, a columnar shape whose distal end has a tapered shape, or the like, yet may be adjusted to meet arbitrary shapes of the recess portions Aa of the hardened regions A.

As illustrated in FIG. 3C, after the hardened regions A are formed, a second plating layer P2 located on the first plating layer P1 is preferably formed on the surfaces of the hardened regions A (an example of part of the surface including the hardened region A). This second plating layer P2 is preferably made of a material having higher rigidity than that of the first plating layer P1 (e.g., Sn plating), and is made of, for example, nickel plating. Note that the second plating layer P2 may be provided only to the hardened region A, or may be provided only on the same surface as the surfaces of the first branched piece 11 and the second branched piece 12 provided with the hardened regions A. Furthermore, the second plating layer P2 is preferably made of a material having higher rigidity than that of the first plating layer P1 as described above, even when the second plating layer P2 is made of the same material as (or a material having rigidity similar to) that of the first plating layer Pl or a material having lower rigidity than that of the first plating layer P1, it is possible to improve the strength of the hardened regions A by providing the second plating layer P2.

As illustrated in FIG. 6 (modified example), in place of the arc-shaped portions 11c and 12c, the elastically deformed portion 10 may include round surface-shaped portions 11d and 12d that are located at the peripheral edge of the cross section perpendicular to the press-fitting direction D2, and have R-chamfered shapes at each (at least one) of the four corner part regions 11f and 12f (see FIG. 9) in contact with the through hole 111. The round surface-shaped portions 11d and 12d are also provided entirely over, for example, the elastically deformed portion 10 in the press-fitting direction D2, yet may be provided at at least part of the elastically deformed portion 10 that can come into contact with the through hole 111. Note that the elastically deformed portion 10 including the round surface-shaped portions 11d and 12d may be formed by chamfering as a post-process, but may be formed by any molding method, pressing method, or the like.

The base portion 20 is provided integrally with the elastically deformed portion 10 on the Z direction negative side of the elastically deformed portion 10. In the example of FIG. 1, the base portion 20 has an L-shaped plate shape. Note that the shape of the base portion 20 is not particularly limited similarly to the shape of the elastically deformed portion 10.

The semiconductor device 100 illustrated in FIG. 1 includes a plurality of the press-fit terminals 1, the substrate 110, a semiconductor element 120, a case 130, a laminated substrate 140, the metal base 150, and wirings 161 to 163.

The substrate 110 is disposed above the case 130. The substrate 110 is provided with the through hole 111 for electrical connection as an example of an insertion hole into which the elastically deformed portion 10 is press-fitted. An unillustrated plating layer made of, for example, copper is formed on the surface of this through hole 111. Note that the substrate 110 is an example of a member electrically connected to the press-fit terminal 1.

The semiconductor element 120 is joined onto a first conductor plate 141 by a conductive joining material (not illustrated) such as solder. The semiconductor element 120 is formed of, for example, a Reverse Conducting (RC)-Insulated Gate Bipolar Transistor (IGBT) element obtained by integrating an IGBT element that is a switching element and a diode element such as a Free Wheeling Diode (FWD) element connected in inverse parallel to this IGBT element and the switching element. The switching element and the diode element in the semiconductor element 120 are not limited to be formed on a Si substrate, and may be formed on a semiconductor substrate using a wide band gap semiconductor such as Silicon Carbide (SiC) or Gallium Nitride (GaN), for example. This type of the semiconductor element 120 has a lower surface and an upper surface provided with unillustrated electrodes. The semiconductor element 120 is electrically connected to the wirings 161 and 163 by a conductive joining material at an electrode provided on the upper surface. Furthermore, the semiconductor element 120 is connected to the press-fit terminal 1 on one side (Y direction negative side) in FIG. 1 via the wiring 163, and is connected to the press-fit terminal 1 in FIG. 1 on the other side (Y direction positive side) via the wirings 161 and 162 and the second conductor plate 142. Note that the press-fit terminal 1 can be used as a main terminal such as an output terminal and an input terminal (a P terminal and an N terminal), or an optional terminal such as a control terminal.

The case 130 has, for example, a quadrangular cylindrical shape whose center axis is the Z direction, and houses the semiconductor element 120 and the like. The case 130 is formed, for example, using an insulating resin material such as Poly Phenylene Sulfide (PPS) or Poly Amide (PA). The case 130 is bonded to the upper surface of the metal base 150.

The case 130 is integrally molded with the plurality of press-fit terminals 1 in a state where both ends of the press-fit terminals 1 are exposed. Note that the semiconductor element 120, the first conductor plate 141, a second conductor plate 142, and the like in the case 130 are sealed using a sealing material M. This sealing material M is, for example, an epoxy resin, silicone gel, or the like. Furthermore, a cover is preferably provided above this sealing material M and over the entire XY plane of a hollow portion of the case 130.

The laminated substrate 140 includes the semiconductor element 120 mounted thereon and electrically connected to the press-fit terminal 1, and includes the first conductor plate 141, the second conductor plate 142, a third conductor plate 143, and an insulating plate 144. The first conductor plate 141 and the second conductor plate 142 are provided on the upper surface of the insulating plate 144, and the third conductor plate 143 is provided on the lower surface of the insulating plate 144. The laminated substrate 140 is, for example, a Direct Copper Bonding (DCB) substrate or an Active Metal Brazing (AMB) substrate.

The first conductor plate 141 and the second conductor plate 142 are members that function as wiring members in an inverter circuit and are formed of, for example, a metal plate, a metal foil, or the like such as copper, aluminum, or the like. The first conductor plate 141 and the second conductor plate 142 may be also referred to as conductor layers, conductive layers, conductor patterns, wiring patterns, or the like.

The third conductor plate 143 is a member that functions as a heat conducting member that conducts heat generated in the inverter circuit to the metal base 150 and is formed of, for example, a metal plate, a metal foil, or the like such as copper, aluminum, or the like. The third conductor plate 143 is bonded to the metal base 150 by a joining material J such as solder. The third conductor plate 143 may be also referred to as a heat dissipation layer, a heat dissipation plate, a conductor pattern, a heat dissipation pattern, or the like.

The insulating plate 144 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating plate 144 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The metal base 150 is a rectangular plate-shaped member. The metal base 150 is a member that functions as a heat conducting member that conducts heat generated by the semiconductor element 120 to the unillustrated cooler, and is formed of, for example, a metal plate such as a copper plate or an aluminum plate. Note that the metal base 150 and the cooler are connected via a thermal conductive material such as a thermal grease or a thermal compound. Note that the metal base 150 may have a function of a cooler.

The wirings 161 to 163 are, for example, lead frames or wires. The wiring 161 connects the semiconductor element 120 and the second conductor plate 142. The wiring 162 connects the second conductor plate 142 and the base portion 20 of the press-fit terminal 1 on the Y direction positive side. The wiring 163 connects the semiconductor element 120 and the base portion 20 of the press-fit terminal 1 on the Y direction negative side.

The case where the press-fit terminal 1 is disposed in the semiconductor device 100 has been described as an example in the above description. However, the application of the press-fit terminal 1 is not limited to the semiconductor device 100, and may be used in any device. Furthermore, a circuit of the semiconductor device 100 includes a switching element, a diode element, and the like inside the semiconductor element 120. However, the semiconductor device 100 may constitute any circuit such as a single-phase voltage half-bridge inverter circuit, a single-phase full-bridge inverter circuit, or a three-phase AC inverter circuit. In addition, the above description of the semiconductor device 100 is merely an example, and the semiconductor device 100 may include the laminated substrate 140 on which the semiconductor element 120 electrically connected to the press-fit terminal 1 is mounted.

Next, insertion of the substrate 110 (press-fitting of the press-fit terminal 1) will be described with reference to front views of FIGS. 4A and 4B.

First, as illustrated in FIG. 4A, for example, a manufacturing device of the semiconductor device 100 positions the positions in the X direction and the Y direction of the plurality of through holes 111 of the substrate 110 at the positions in the X direction and the Y direction of the plurality of press-fit terminals 1, and then moves the substrate 110 to the Z direction negative side (substrate insertion direction D3). As a result, the elastically deformed portion 10 exposed upward from the case 130 illustrated in FIG. 1 described above enters the through hole 111 of the columnar shape. Since the maximum length L (see FIG. 2) of the elastically deformed portion 10 in the deformation direction D1 (X direction) is larger than the inner diameter of the through hole 111 before the elastically deformed portion 10 is elastically deformed, only the distal ends 11a and 12a of the first branched piece 11 and the second branched piece 12 enter the through hole 111. Note that, instead of the substrate 110 moving to the Z direction negative side as described above, the press-fit terminal 1 (elastically deformed portion 10) may be press-fitted by moving the press-fit terminal 1 (case 130) to the Z direction positive side.

Next, when the substrate 110 is pressed in the substrate insertion direction D3, both ends in the deformation direction D1 of the first branched piece 11 and the second branched piece 12 come into with the inner peripheral wall of the through hole 111, and then contact pressures apply to the first branched piece 11 and the second branched piece 12, so that the elastically deformed portion 10 is elastically deformed so as to be compressed in the deformation direction D1. When this elastically deformed portion 10 is deformed, the distal ends 11a and 12a of the first branched piece 11 and the second branched piece 12 are elastically deformed so as to approach each other. In other words, the elastic deformation occurs when the press-fit terminal 1 is press-fitted into the through hole 111 in the press-fitting direction D2. Furthermore, press-fitting the press-fit terminal 1 into the through hole 111 deforms the first branched piece 11 and the second branched piece 12 in the deformation direction D1 vertical to the press-fitting direction D2, and makes the distance therebetween shorter.

As illustrated in FIG. 4B, when insertion of the substrate 110 in the substrate insertion direction D3 is completed, the elastically deformed portion 10 is further compressed in the deformation direction D1, and the distal end 11a of the first branched piece 11 and the distal end 12a of the second branched piece 12 come into contact with each other. In this state, the elastic force of the elastically deformed portion 10 acts strongly, so that the elastically deformed portion 10 is hardly detached even when pulled in the direction opposite to the press-fitting direction D2. Consequently, it is possible to electrically connect the press-fit terminal 1 and the through hole 111, and implement the substrate 110 without soldering.

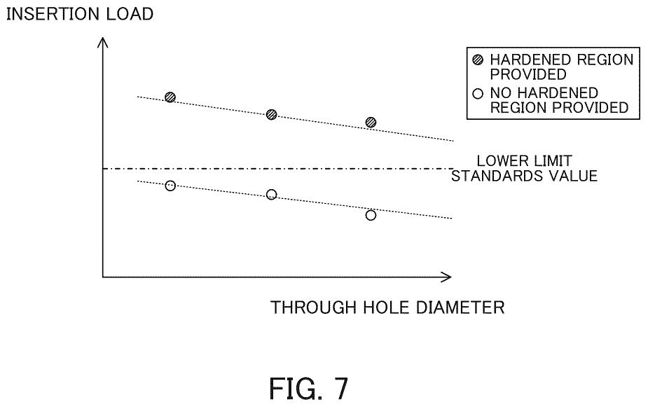

As illustrated in FIG. 7, in a case where the hardened regions A are not provided to the first branched piece 11 and the second branched piece 12 (the first branched piece 11 and the second branched piece 12 including the arc-shaped portions 11c and 12c as illustrated in FIG. 5) (indicated by white circles), the insertion load at the time of insertion (press-fitting) of the press-fit terminal 1 into the through hole 111 falls below the lower limit standards value regardless of the diameter of the through hole 111 as described above with reference to FIG. 10.

By contrast with this, in a case where the hardened regions A are provided to the first branched piece 11 and the second branched piece 12 (the first branched piece 11 and the second branched piece 12 including the arc-shaped portions 11c and 12c as illustrated in FIG. 5) as in the present embodiment (indicated by circles with diagonal lines), the insertion load at the time of insertion (press-fitting) of the press-fit terminal 1 into the through hole 111 tends to decrease as the diameter of the through hole 111 increases, yet exceeds the lower limit standards value regardless of the diameter of the through hole 111, and satisfies the standards.

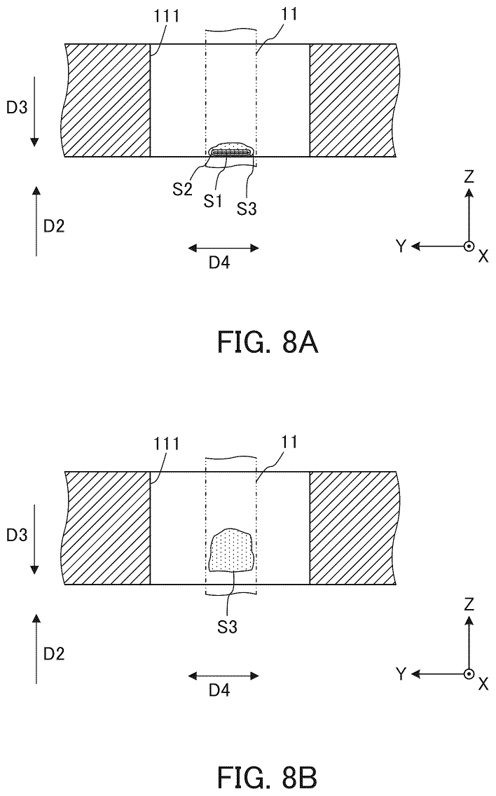

As described above, by providing the hardened regions A, it is possible to increase the insertion load without changing the length, the width, the thickness, and the shape of the press-fit terminal 1, the diameter of the through hole 111, and the like. Here, the insertion load increases by providing the hardened regions A because, when the elastically deformed portion 10 (the first branched piece 11 on one side is indicated by a two-dot chain line) provided with the hardened regions A is press-fitted as illustrated in FIG. 8A (see a portion VIII in FIG. 4B), the reaction forces of the hardened regions A increase, and therefore a high stress portion S1, a middle stress portion S2, and a low stress portion S3 of the through hole 111 concentrate at an upstream side end part (an end part on the Z direction negative side) in the press-fitting direction D2, and increase a contact load after the press-fitting.

By contrast with this, when the first branched piece 11 in a case where the hardened regions A are not provided is press-fitted, as illustrated in FIG. 8B (comparative example), the low stress portion S3 of the through hole 111 is dispersed in the press-fitting direction D2, and the high stress portion S1 and the middle stress portion S2 larger than the low stress portion S3 are not produced. Therefore, the insertion load does not increase.

Note that the above description has cited the example where the hardened regions A are provided such that the insertion load of the press-fit terminal 1 exceeds the lower limit standards value illustrated in FIG. 7. However, it is effective to provide the hardened regions A to increase a pull-out load (holding force) of the press-fit terminal 1. Furthermore, in a case of such a relationship between the press-fit terminal 1 and the through hole 111 that the unillustrated plating layer of the through hole 111 or the first plating layer P1 of the press-fit terminal 1 is hardly scraped, the insertion load and the pull-out load are reduced, so that it can be said that it is effective to select the area and the strength of the hardened regions A according to required performance. At this time, the length, the width, the thickness, and the shape of the press-fit terminal 1, the diameter of the through hole 111, and the like may be also appropriately adjusted.

The above-described press-fit terminal 1 according to the present embodiment includes the first branched piece 11 and the second branched piece 12 that are examples of a pair of branched portions, and the base portion 20. The first branched piece 11 and the second branched piece 12 are branched into two from the root portions 11b and 12b on the base portion 20 side while being separated, and have the distal ends 11a and 12a curved so as to approach each other, are press-fitted into the through hole 111 (an example of the insertion hole) in the press-fitting direction D2, and elastically deformed. Furthermore, the first branched piece 11 and the second branched piece 12 include the hardened regions A located closer to the root portions 11b and 12b side than the maximum length L1 portion in the deformation direction D1 before being press-fitted into the through hole 111. From another point of view, the press-fit terminal 1 includes the first branched piece 11 and the second branched piece 12 that are an example of a pair of branched portions, and the base portion 20, and the first branched piece 11 and the second branched piece 12 are branched into two from the root portions 11b and 12b on the base portion 20 side while being separated, have the distal ends 11a and 12a curved so as to approach each other, and include the hardened regions A that are located closer to the root portions 11b and 12b side than the maximum length L1 portion at which a separation distance between the first branched piece 11 and the second branched piece 12 is maximum. Furthermore, from the above other viewpoint, elastic deformation occurs when the press-fit terminal 1 is press-fitted into the through hole 111 in the press-fitting direction D2, this press-fitting deforms the first branched piece 11 and the second branched piece 12 in the deformation direction D1 vertical to the press-fitting direction D2, and makes the distance therebetween shorter. Furthermore, the semiconductor device 100 according to the present embodiment includes the press-fit terminal 1 and the laminated substrate 140 that includes the semiconductor element 120 mounted thereon and electrically connected to this press-fit terminal 1.

As a result, even when the relationship between the press-fit terminal 1 and the through hole 111 is, for example, such a relationship that the plating layer of the through hole 111 or the first plating layer P1 of the press-fit terminal 1 is hardly scraped and the insertion load of the press-fit terminal 1 into the through hole 111 is reduced, it is possible to increase the insertion load by providing the hardened regions A to the press-fit terminal 1 without changing the length, the width, the thickness, and the shape of the press-fit terminal 1, the diameter of the through hole 111, and the like. Consequently, according to the present embodiment, it is possible to satisfy the performance required for the press-fit terminal 1.

Furthermore, in the present embodiment, the first branched piece 11 and the second branched piece 12 include the arc-shaped portions 11c and 12c whose curvature centers are on the center side of the through hole 111 at the both ends in the deformation direction D1 of the cross section perpendicular to the press-fitting direction D2 when press-fitted.

Consequently, as compared with an aspect where the peripheral edges of the first branched piece 11 and the second branched piece 12 have the angular shapes (see the corner part regions 11f and 12f illustrated in FIG. 9.), it is possible to prevent the plating layer of the through hole 111 and the first plating layer P1 of the press-fit terminal 1 from being scraped when the press-fit terminal 1 is press-fitted into the through hole 111. Consequently, it is also possible to improve reliability of electrical connection. Furthermore, by providing the hardened regions A to the first branched piece 11 and the second branched piece 12 as described above, it is possible to prevent the insertion load from falling below the lower limit standards value.

Furthermore, in the present embodiment, the hardened regions A are provided on at least one of the both end surfaces of the first branched piece 11 and the second branched piece 12 in the width direction D4 (Y direction) perpendicular to the press-fitting direction D2 and the deformation direction D1.

Consequently, as compared with an aspect where the hardened regions A are provided to the curved surfaces that are the both end surfaces in the deformation direction D1 of the first branched piece 11 and the second branched piece 12, it is possible to easily machine the hardened regions A by providing the hardened regions A on the plane. Note that, by providing the hardened regions A on the both end surfaces in the width direction D4 (Y direction) of the first branched piece 11 and the second branched piece 12, it is possible to prevent elastic deformation of the first branched piece 11 and the second branched piece 12 from varying in the width direction D4 (Y direction) as compared with a case where the hardened region A is provided only to one end surface.

Furthermore, in the present embodiment, the hardened regions A are located closer to the root portions 11b and 12b side than the position of the through hole 111 after press-fitting in the press-fitting direction D2.

Consequently, it is possible to prevent contact of the hardened regions A or the vicinity thereof with the through hole 111 from significantly scraping the plating layer of the through hole 111 and the first plating layer P1 of the press-fit terminal 1.

Furthermore, in the present embodiment, the hardened regions A are formed by plastic working.

Consequently, it is possible to form the hardened regions A by simple machining as compared with an aspect where the hardened regions A are formed by applying heat treatment, performing laser processing, or adding a reinforcing material.

Furthermore, in the present embodiment, the first branched piece 11 and the second branched piece 12 include the first plating layer P1 provided on the surface, and the second plating layer P2 located on the first plating layer P1 at part of the surface including the hardened region A.

Consequently, it is possible to further increase the hardness of the hardened region A by the second plating layer P2. Furthermore, it is also possible to prevent the first plating layer P1 from being partially scraped and the surfaces of the first branched piece 11 and the second branched piece 12 from being exposed when the hardened regions A are formed.

Furthermore, in the present embodiment, the second plating layer P2 is made of a material having higher rigidity than that of the first plating layer P1.

Consequently, the second plating layer P2 can further harden the hardened regions A.

Hereinafter, the invention described in the description and the drawings of the present application will be described as supplementary notes.

### Supplementary Note 1

A press-fit terminal includes:
a base portion; and
a pair of branched portions that are branched into two from a root portion on a side of the base portion while being separated from each other, have distal ends curved to approach each other, are press-fitted into an insertion hole in a press-fitting direction, and elastically deform, and
the pair of branched portions include hardened regions that are located closer to a side of the root portion than a maximum length portion in a deformation direction before being press-fitted into the insertion hole.

### Supplementary Note 2

In the press-fit terminal described in supplementary note 1, the pair of branched portions include arc-shaped portions whose curvature centers are on a center side of the insertion hole at both ends in the deformation direction of a cross section perpendicular to the press-fitting direction when press-fitted.

### Supplementary Note 3

In the press-fit terminal described in supplementary note 1 or 2, the hardened regions are provided on at least one of both end surfaces of the pair of branched portions in a width direction perpendicular to the press-fitting direction and the deformation direction.

### Supplementary Note 4

In the press-fit terminal described in any one of supplementary note 1 to 3, the hardened regions are located closer to the side of the root portion than a position of the insertion hole after the press-fitting in the press-fitting direction.

### Supplementary Note 5

In the press-fit terminal described in any one of supplementary note 1 to 4, the hardened regions are formed by plastic working.

### Supplementary Note 6

In the press-fit terminal described in any one of supplementary note 1 to 5, the pair of branched portions include a first plating layer provided on a surface, and a second plating layer located on the first plating layer at part of the surface including the hardened regions.

### Supplementary Note 7

In the press-fit terminal described in supplementary note 6, the second plating layer is made of a material having higher rigidity than rigidity of the first plating layer.

### Supplementary Note 8

A semiconductor device includes:
the press-fit terminal described in any one of supplementary notes 1 to 7; and
a laminated substrate on which a semiconductor element electrically connected to the press-fit terminal is mounted.

### Supplementary Note 9

A press-fit terminal includes:
a base portion; and
a pair of branched portions that are branched into two from a root portion on a side of the base portion while being separated from each other, have distal ends curved to approach each other, and elastically deform, and
the pair of branched portions include hardened regions that are located closer to a side of the root portion than a maximum length portion at which a separation distance between the pair of branched portions is maximum.

### Supplementary Note 10

In the press-fit terminal described in supplementary note 9,
the elastic deformation is performed when the press-fit terminal is press-fitted into an insertion hole in a press-fitting direction, and
the press-fitting deforms the pair of branched portions in a deformation direction vertical to the press-fitting direction, and makes a distance between the pair of branched portions shorter.

### Supplementary Note 11

A semiconductor device includes:
the press-fit terminal described in any one of supplementary notes 9 and 10; and
a laminated substrate on which a semiconductor element electrically connected to the press-fit terminal is mounted.

### Industrial Applicability

As described above, the present invention provides an effect of satisfying performance required for a press-fit terminal, and is useful for a semiconductor device such as a power semiconductor device, for example.

What is claimed is:

1. A press-fit terminal comprising:
a base portion; and
a pair of branched portions that are branched from the base portion, the pair of branched portions being separated from each other and being curved, each branch portion having
a distal end,
a maximum length portion, and
a root portion,
the two root portions being connected to the base portion, the two distal ends approaching each other, and the pair of branched portions having a maximum separation distance in a deformation direction between the two maximum length portions, wherein
the pair of branched portions are elastically deformable to be press-fitted, in a press-fitting direction perpendicular to the deformation direction, into an insertion hole, and
each of the pair of branched portions includes a hardened region, which is located closer to the root portion of said each branched portion than to the maximum length portion of said each branched portion in the deformation direction.

2. The press-fit terminal according to claim 1, wherein in a cross section perpendicular to the press-fitting direction, the pair of branched portions include arc-shaped portions respectively at two ends of the press-fit terminal in the deformation direction, each arc-shaped portion being shaped to have a curvature center that is within the insert hole when press-fitted.

3. The press-fit terminal according to claim 1, wherein
each of the pair of branched portions has two end surfaces in a width direction perpendicular to the press-fitting direction and the deformation direction, the hardened region being provided on at least one of the two end surfaces thereof.

4. The press-fit terminal according to claim 1, wherein
each of the hardened regions is so configured as to be located closer to the root portion than to a position of the insertion hole after the press-fitting in the press-fitting direction.

5. The press-fit terminal according to claim 1, wherein the hardened regions are formed by plastic working.

6. The press-fit terminal according to claim 1, wherein each of the pair of branched portions includes
a first plating layer provided on a surface thereof, and
a second plating layer formed partially on the first plating layer, at a location corresponding to the hardened region thereof.

7. The press-fit terminal according to claim 6, wherein the second plating layer is made of a material having higher rigidity than rigidity of the first plating layer.

8. A semiconductor device comprising:
the press-fit terminal according to claim 7;
a laminated substrate; and
a semiconductor element mounted on the laminated substrate and electrically connected to the press-fit terminal.

9. A semiconductor device comprising:
the press-fit terminal according to claim 6;
a laminated substrate; and
a semiconductor element mounted on the laminated substrate and electrically connected to the press-fit terminal.

10. A semiconductor device comprising:
the press-fit terminal according to claim 5;
a laminated substrate; and
a semiconductor element mounted on the laminated substrate and electrically connected to the press-fit terminal.

11. A semiconductor device comprising:
the press-fit terminal according to claim 4;
a laminated substrate; and
a semiconductor element mounted on the laminated substrate and electrically connected to the press-fit terminal.

12. A semiconductor device comprising:
the press-fit terminal according to claim 3;
a laminated substrate; and
a semiconductor element mounted on the laminated substrate and electrically connected to the press-fit terminal.

13. A semiconductor device comprising:
the press-fit terminal according to claim 2;
a laminated substrate; and
a semiconductor element mounted on the laminated substrate and electrically connected to the press-fit terminal.

14. A semiconductor device comprising:
the press-fit terminal according to claim 1;
a laminated substrate; and
a semiconductor element mounted on the laminated substrate and electrically connected to the press-fit terminal.
